(19) United States
(12) Patent Application Publication
(10) Pub. No.: US 2006/0236171 A1
(43) Pub. Date: Oct. 19, 2006

(54) METHOD FOR DETECTING AND CORRECTING ERRORS OF ELECTRONIC APPARATUS

(76) Inventors: Che-Hsien Hu, Taipei City (TW); Yi-Hung Shen, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,022

(22) Filed: Jul. 20, 2005

(30) Foreign Application Priority Data
Apr. 13, 2005 (TW) 94111615

(51) Int. Cl. G01R 31/28

(52) U.S. Cl. 714/724

(57) ABSTRACT

A method for detecting and correcting the error of an electronic apparatus is provided. An embedded controller whose power is independently supplied is used to detect and store the error code from the internal devices of the electronic apparatus. First, the error status of the electronic apparatus is detected to obtain an error code corresponding thereto. Then, the error code is stored in either an external memory or an internal memory unit of the controller. When the controller receives a control signal, the error code is accessed through a wireless transmission apparatus. Moreover, the error status of the electronic apparatus is analyzed according to the error code to determine a corresponding debug method. For example, a correcting program code is programmed into the electronic apparatus by a wireless transmission method to achieve the debug purpose.

### CROSS-REFERENCE TO RELATED APPLICATION

This application claims the priority benefit of Taiwan application serial no. 94111615, filed on Apr. 13, 2005. All disclosure of the Taiwan application is incorporated herein by reference.

### BACKGROUND OF THE INVENTION

1. Field of the Invention

The present invention relates to a method for error detection and correction, and more particularly, to a method for detecting and correcting error of an electronic apparatus even if the electronic apparatus is turned off.

2. Description of the Related Art

When consumers use electronic products, errors or failures of devices of the electronic products may be occurred because of the user's personal behaviors and environment. To avoid electronic product failures caused by the errors, manufacturers provide an error detection system to detect the operation status of internal devices of the electronic apparatus. Generally, an electronic apparatus comprises several sets of alarm lights or rings to show the operational status of internal devices. When an error occurs, such as CUP over-heat or failure of the fan, the alarm lights or rings will flash or ring to achieve alarming function. The alarm method described above, however, can only indicate which device that generates the error signal when the error happens but cannot provide useful data for error correction.

For a prior art electronic apparatus, such as a computer system, a boot-up error code is provided to collect data of the apparatus before the computer system is turned on. FIG. 1 is a block diagram showing a prior art apparatus. The prior art apparatus comprises the boot-up error code accessing apparatus 120, which is disposed on the to-be-tested computer mother board 110; and the boot-up error code collecting apparatus 140, which is disposed on the remote console 130. They are coupled to each other through the signal connection line 150, such as a cable line or fixture probe. The connection line 150 is used to transmit the boot-up error code and the control signals between the boot-up error code accessing apparatus 120 and the boot-up error code collecting apparatus 140. The prior art method, however, can only be performed when the computer is turned on. When the system is failed and turned off, the error code cannot be accessed to find out the failed device or causes.

### SUMMARY OF THE INVENTION

Accordingly, the present invention is directed to a method for detecting and correcting an error of an electronic apparatus. The embedded controller, whose power is independently supplied, monitors the system situation. When an error occurs to the system and the system is turned off, the error code stored in the controller is analyzed to find the failed internal device and the failed reason. By a wireless transmission method, the error code is accessed when the system is turned off. Then the correcting program code is programmed in the electronic apparatus to achieve the purpose of detecting and correcting error.

The present invention is also directed to a method for detecting and correcting an error of an electronic apparatus. The embedded controller, whose power is independently supplied, detects the error occurrence of the electronic apparatus to obtain the error code corresponding thereto when the electronic apparatus is turned off. The error code is then transmitted to a wireless apparatus to correct the electronic apparatus.

According to the objects above, the present invention provides a method for detecting and correcting errors of an electronic apparatus. The method detects and stores an error code of a to-be-tested device in the electronic apparatus when the electronic apparatus is turned off. According to the method of the present invention, the preset specification for safely operating the to-be-tested device is set. The controller detects the to-be-tested device and receives a detecting signal. The detecting signal comprises a status value of the to-be-tested device. Then, it is determined whether the status value is over the preset specification. If the status value is out of the specification, the error code corresponding to the status value is generated. The error code is then stored in a memory. The controller determines whether a control signal is received. If the control signal is received, the error code, which is stored by the controller, is accessed. The error code is then transmitted to a wireless transmission apparatus. An error occurrence of the electronic apparatus is determined according to the error code. A debug method corresponding to the error occurrence is determined to debug the error occurrence.

According to the description above, the present invention provides a method for detecting and correcting errors of an electronic apparatus. The method detects and stores an error code of a to-be-tested device in the electronic apparatus when the electronic apparatus is turned off. According to the method of the present invention, first an error occurrence of the electronic apparatus is detected to obtain an error code corresponding thereto. The error code is then transmitted to a wireless transmission apparatus. The electronic apparatus is corrected according to the error code.

According to the method for detecting and correcting errors of an electronic apparatus of a preferred embodiment of the present invention, the method of obtaining the error code comprises the following steps. First, a status value of the to-be-tested device of the electronic apparatus is detected. At least one preset specification for safely operating the to-be-tested device is set. Then, it is determined whether the status value is out of the preset specification. Finally, if the status value is out of the specification, the error code corresponding to the status value is generated.

According to the method for detecting and correcting errors of an electronic apparatus of a preferred embodiment of the present invention, the status value of the electronic apparatus described above includes a temperature status or a fan operation status, for example.

According to the method for detecting and correcting errors of an electronic apparatus of a preferred embodiment of the present invention, the electronic apparatus stores the error code in a memory and determines whether a control signal is received. If the control signal is received, the error code, which is stored by the controller, is accessed. Wherein, the step of transmitting the error code to the wireless transmission apparatus means to transmit the whole error code to the wireless transmission apparatus.

According to the method for detecting and correcting errors of an electronic apparatus of a preferred embodiment of the present invention, the step of correcting the electronic apparatus according to the error code comprises obtaining the error code through the wireless transmission apparatus, determining an error occurrence of the electronic apparatus according to the error code, and determining a debug method corresponding to the error occurrence, and performing the debug method.

According to the method for detecting and correcting errors of an electronic apparatus of a preferred embodiment of the present invention, the debug method above comprises changing a failed device or programming a correcting program in the electronic apparatus.

According to the method for detecting and correcting errors of an electronic apparatus of a preferred embodiment of the present invention, the debug method above includes programming the correcting program into the electronic apparatus through the wireless apparatus, for example.

According to the method for detecting and correcting errors of an electronic apparatus of a preferred embodiment of the present invention, the electronic apparatus above comprises an embedded controller. Even if the electronic apparatus is turned off, a power remains being supplied to the embedded controller to obtain the error code.

With the controller of the present invention, whose power is independently supplied, the error code can be stored at any time. In the prior art technology, the steps of detecting and collecting error codes are not triggered until the mother board of the electronic apparatus is turned on. Compared with the prior art method, the method of the present invention can monitor the operation status of the electronic apparatus at any time. In addition, the wireless transmission apparatus of the present invention transmits the error code. Even if the electronic apparatus is not turned on, the error code can be accessed. The correcting program code thus can be programmed in the electronic apparatus for the detecting and correcting purposes.

The above and other features of the present invention will be better understood from the following detailed description of the preferred embodiments of the invention that is provided in communication with the accompanying drawings.

### BRIEF DESCRIPTION OF THE DRAWINGS

FIG. 1 is a block diagram showing a prior art apparatus.

FIG. 2 is a flowchart showing an operational method of a computer system according to a preferred embodiment of the present invention.

FIG. 3 is a schematic module drawing of a computer system apparatus according to a preferred embodiment of the present invention.

FIG. 4 is a flowchart showing a method for detecting and correcting an error of a computer system according to a preferred embodiment of the present invention.

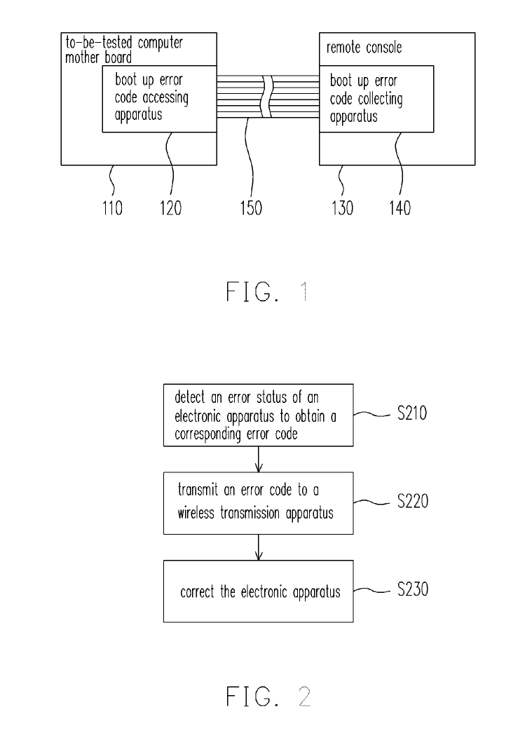

### DESCRIPTION OF SOME EMBODIMENTS

According to an embodiment of the present invention, a electronic apparatus can be, for example, a computer system. The computer system comprises several sets of alarm lights or rings. When an error occurrence, such as CUP over-heat or failed operation of a fan, occurs, the method of the present invention for detecting and correcting the error of the electronic apparatus is applied. According to the method, a temperature sensor or the fan near the computer CPU is coupled to an embedded controller to detect function of the internal devices of the computer.

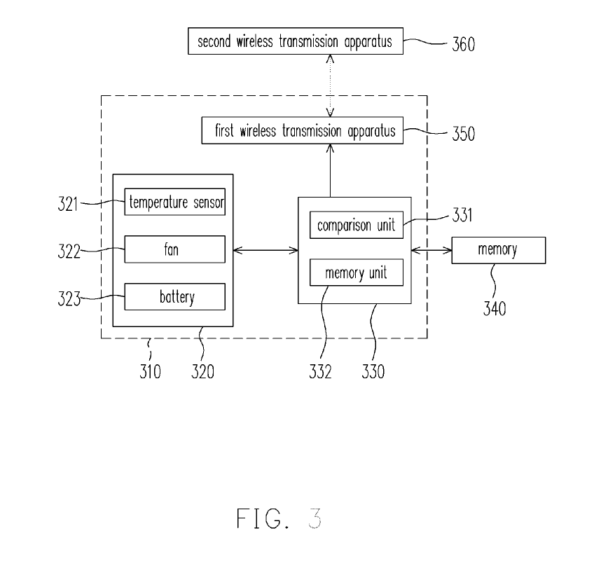

FIG. 2 is a flowchart showing an operational method of a computer system according to a preferred embodiment of the present invention. Referring to FIG. 2, while the electronic apparatus is turned off, the controller of the embodiment detects and stores an error code of a to-be-tested device. According to the method, the embedded controller detects the electronic apparatus. Once an error status of the to-be-tested device of the electronic apparatus is detected, the error code corresponding to a failed device is obtained (step S210). The error code is then transmitted to a wireless transmission apparatus (step S220). The error code is analyzed. According to the analysis result of the error code, a debug method is determined to debug the electronic apparatus (step S230).

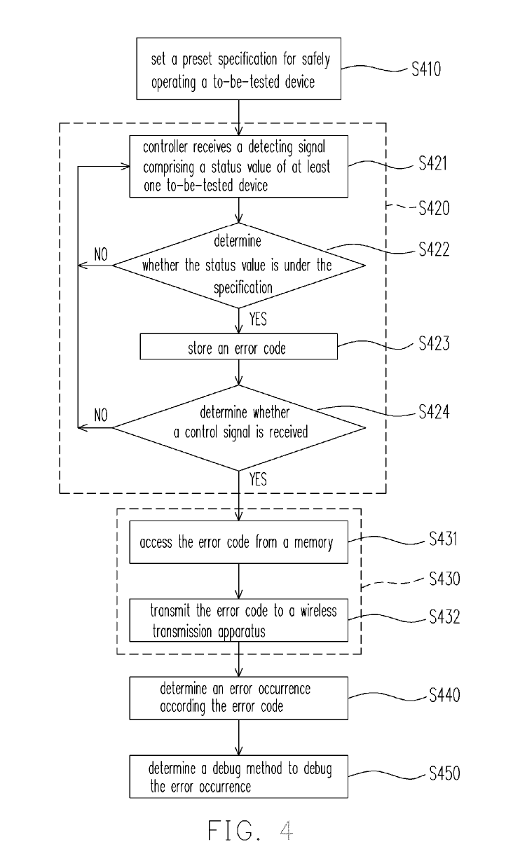

FIG. 3 is a schematic module drawing of a computer system apparatus according to a preferred embodiment of the present invention. Referring to FIG. 3, the computer system 310 comprises, for example, the to-be-tested device 320 and the controller 330, which are coupled to a memory 340. Wherein, the to-be-tested device 320 of the computer system 310 comprises, for example, the temperature sensor 321, the fan 322 and a battery 323. The controller 330 is the embedded controller, and comprises a comparison unit 331 and a memory unit 332. The controller 330 is coupled to a first wireless transmission apparatus 350 which transmits the error code temporarily stored in the memory to a second wireless apparatus 360 for access purpose.

FIG. 4 is a flowchart showing a method for detecting and correcting an error of a computer system according to a preferred embodiment of the present invention. Referring to FIGS. 3 and 4, at least one preset specification corresponding to a status value is set in step S410. The controller 330 stores the preset specification for the to-be-tested device 320 in a memory unit 332. Step S420 comprises an internal data control flow of the controller 330. In step S421, the controller 330 periodically detects the operation of the to-be-tested device 320 of the electronic apparatus and receives a detecting signal. Wherein, the detecting signal comprises the status value of at least one to-be-tested device of the electronic apparatus. Step S422 determines whether the status value is within the preset specification. If the status value is under the preset specification, the flow is back to step S421 to continuously detect the next detecting signal. If the status value is out of the specification, it means that the to-be-tested device 320 is not under a safe operation. Then the error code corresponding to the statue value is generated. In step S423, the controller 330 transmits the error code to the memory 340 or stores the error code in the memory unit 332. In step S424, the controller 330 determines whether a control signal is received to either access the error code stored in the memory 340 or the memory unit 332 or not. If the control signal is not received, step S421 is repeated to continuously detect the next detecting signal. If the control signal is received, step S430 is performed which means the error code is accessed. Step S430 comprises the following steps. In step S431, the error code is accessed from either the memory 340 or the memory unit 332. In step S432, the error code is transmitted to the first wireless transmission apparatus 350. The second wireless transmission apparatus 360 then accesses the error code of the computer system 310 by a wireless transmission method. Wherein, the wireless transmission method applied between the wireless transmission apparatuses 350 and 360 comprises, for example, a Bluetooth method, an infrared ray (IR) method or a radio frequency identification (RFID) method. In step S440, the accessed error code is then used to determine the failed to-be-tested device 320 or error occurrence. In step S450, a debug method is further determined according to the error occurrence. The debug method comprises, for example, changing the failed device, or programming a correcting program. Then, the debug method is used to debug the error occurrence.

The detection method of the controller above detects the CPU over-heat, for example. The temperature sensor adjacent to the CPU is controlled by the controller coupled to the system management bus (SMBus). The CPU temperature can be periodically detected. When the CPU temperature is over a preset temperature, the error code corresponding to the CPU over-heat is stored in the external memory or the internal memory unit of the controller to avoid the damage caused by the CPU over-heat.

The detection method of the controller above may detect the fan error, for example. The fan speed or switch of the fan is controlled by the controller. When the controller outputs the control signal to the fan and does not receive the pulse width modulation (PWM) signal from the fan, it is determined that the fan fails. The controller stores the error code corresponding to the failed fan in either the external memory or the internal memory unit of the controller.

According to the method for detecting and correcting error of the electronic apparatus, the controller, whose power is independently supplied, monitors the operation of the electronic apparatus. Even if the electronic apparatus is turned off, the error code can still be accessed and the correcting data can be programmed by the wireless transmission method. These features are not disclosed in the prior art technology.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A method for detecting and correcting errors of an electronic apparatus, the method detecting and storing an error code of a to-be-tested device in the electronic apparatus during an off status, the method comprising:
a. detecting the to-be-tested device and receiving a detecting signal by a controller, the detecting signal comprising a status value of the to-be-tested device;
b. determining whether the status value is over a preset specification, wherein the preset specification represents a safe operating range for the to-be-tested device;
c. generating the error code corresponding to the status value if the status value is out of the specification;
d. storing the error code in a memory;
e. determining by the controller whether a control signal is received;
f. accessing the stored error code if the control signal is received by the controller;
g. transmitting the error code to a wireless transmission apparatus; and
h. determining an error occurrence of the electronic apparatus according to the error code, and determining a debug method corresponding to the error occurrence to debug the error occurrence.

2. The method for detecting and correcting errors of an electronic apparatus of claim 1, further comprising after the step e:
f1. continuously detecting the status value of the to-be-tested device if the control signal is not received.

3. The method for detecting and correcting errors of an electronic apparatus of claim 1, wherein the wireless transmission apparatus transmits the error code by a wireless transmission method, and the wireless transmission method comprises one of a Bluetooth, an Infrared Ray (IR) and a Radio Frequency Identification (RFID).

4. The method for detecting and correcting errors of an electronic apparatus of claim 1, wherein detecting the to-be-tested device comprises detecting the CPU over-heat by a temperature sensor controlled by the controller coupled to a system management bus (SMBus).

5. The method for detecting and correcting errors of an electronic apparatus of claim 1, wherein detecting the to-be-tested device comprising:
detecting error of a fan controlled by the controller; and
determining the fan fails when the controller outputs a control signal to the fan and does not receive a pulse width modulation (PWM) signal from the fan.

6. A method for detecting and correcting errors of an electronic apparatus by a controller, the method detecting and storing an error code of a to-be-tested device in the electronic apparatus during an off status, the method comprising:
a. detecting an error occurrence of the electronic apparatus to obtain an error code corresponding thereto;
b. transmitting the error code to a wireless transmission apparatus; and
c. correcting the electronic apparatus according to the error code.

7. The method for detecting and correcting errors of an electronic apparatus of claim 6, wherein the step a comprises:
a1. setting at least one preset specification for safely operating the to-be-tested device;
a2. detecting a status value of the to-be-tested device of the electronic apparatus;
a3. determining whether the status value is out of the preset specification; and
a4. generating the error code corresponding to the status value if the status value is out of the preset specification.

8. The method for detecting and correcting errors of an electronic apparatus of claim 7, wherein the status value of the electronic apparatus relates to a temperature status or a fan operation status.

9. The method for detecting and correcting errors of an electronic apparatus of claim 6, wherein the step b comprises:
b1. storing the error code in a memory;
b2. determining by the controller whether a control signal is received;
b21. accessing the stored error code if the control signal is received; and
b22. continuously detecting the status value of the to-be-tested device if the control signal is not received.

10. The method for detecting and correcting errors of an electronic apparatus of claim 6, wherein the step c comprises:
c1. obtaining the error code through the wireless transmission apparatus;
c2. determining an error occurrence of the electronic apparatus according to the error code, and determining a debug method corresponding to the error occurrence; and
c3. performing the debug method.

11. The method for detecting and correcting errors of an electronic apparatus of claim 10, wherein the debug method comprises changing a failed device.

12. The method for detecting and correcting errors of an electronic apparatus of claim 10, wherein the debug method comprises programming a correcting program into the electronic apparatus.

13. The method for detecting and correcting errors of an electronic apparatus of claim 12, wherein the correcting program is programmed into the electronic apparatus through the wireless apparatus.

14. The method for detecting and correcting errors of an electronic apparatus of claim 6, wherein the electronic apparatus comprises an embedded controller, and even if the electronic apparatus is turned off, a power remains being supplied to the embedded controller to obtain the error code.

15. The method for detecting and correcting errors of an electronic apparatus of claim 6, wherein the electronic apparatus is a computer system.

16. The method for detecting and correcting errors of an electronic apparatus of claim 6, wherein the wireless transmission apparatus transmits the error code by a wireless transmission method, and the wireless transmission method comprises one of a Bluetooth, an Infrared Ray (IR) and a Radio Frequency Identification (RFID).

17. The method for detecting and correcting errors of an electronic apparatus of claim 6, wherein detecting an error occurrence of the electronic apparatus comprises detecting the CPU over-heat by a temperature sensor controlled by the controller coupled to a system management bus (SMBus).

18. The method for detecting and correcting errors of an electronic apparatus of claim 6, wherein detecting an error occurrence of the electronic apparatus comprising:
detecting error of a fan controlled by the controller; and
determining the fan fails when the controller outputs a control signal to the fan and does not receive a pulse width modulation (PWM) signal from the fan.
